(19) United States
(12) Patent Application Publication
(10) Pub. No.: US 2024/0005049 A1
(43) Pub. Date: Jan. 4, 2024

(54) SYSTEMS AND METHODS FOR GENERATION OF EXPLODED VIEWS OF COMPUTER-AIDED DESIGN MODELS

(71) Applicant: Siemens Industry Software Inc., Plano, TX (US)

(72) Inventors: Istvan Menyhart, Cincinnati, OH (US); Mohsen Rezayat, Cincinnati, OH (US)

(73) Assignee: Siemens Industry Software Inc., Plano, TX (US)

(21) Appl. No.: 18/253,701

(22) PCT Filed: Dec. 18, 2020
(86) PCT No.: PCT/US2020/065913

§ 371 Date: May 19, 2023

(51) Int. Cl. G06F 30/12

(52) U.S. Cl. CPC G06F 30/12

(57) ABSTRACT

A computing system may include a model access engine configured to access a CAD model comprised of multiple CAD parts. The computing system may also include a model explosion engine configured to construct a blocking data structure for the CAD model that stores a blocking state for each pair of CAD parts of the CAD model (210) as well as an explosion graph for the CAD model. Iterative generation of the explosion graph by the model explosion engine may include querying the blocking data structure to determine unblocked CAD parts for which to insert a node into the explosion graph. The model explosion engine may also be configured to generate an exploded view representation of the CAD model using the constructed explosion graph.

### BACKGROUND

Computer systems can be used to create, use, and manage data for products, items, and other objects. Examples of computer systems include computer-aided design (CAD) systems (which may include computer-aided engineering (CAE) systems), visualization and manufacturing systems, product data management (PDM) systems, product lifecycle management (PLM) systems, and more. These systems may include components that facilitate the design, visualization, and simulated testing of product structures and product manufacture.

### BRIEF DESCRIPTION OF THE DRAWINGS

Certain examples are described in the following detailed description and in reference to the drawings.

FIG. 1 shows an example of a computing system that supports generation of exploded views of CAD models according to the present disclosure.

FIG. 2 shows an example construction of a blocking data structure according to the present disclosure in support of exploded CAD model views.

FIG. 3 shows an example construction of an explosion graph by a model explosion engine according to the present disclosure.

FIG. 4 shows an example generation of an exploded view representation by the model explosion engine.

FIG. 5 shows an example of logic that a system may implement to support generation of exploded views of CAD models according to the present disclosure.

FIG. 6 shows an example of a computing system that supports generation of exploded views of CAD models according to the present disclosure.

### DETAILED DESCRIPTION

Modern technological advances have given rise to the design, simulation, and manufacture of increasingly complex products of various types across many different industries. Computer systems may support the design and tracking of products with components numbering in the hundreds of thousands, millions, tens of millions and possibly more. CAD models may be used to model such products, and CAD models may be comprised of CAD parts. As used herein, a CAD part may refer to any discrete object that can be represented digitally (e.g., as CAD data), and CAD parts may be combined to form products or components thereof. Complex objects may thus be represented via CAD models comprised of CAD parts. CAD models may represent different products (e.g., a given CAD model for a hard drive comprised of multiple components represented as CAD parts such as an enclosure, bolts, optical storage components, etc.). CAD models may also represent different sub-systems or components of a given product (e.g., electrical and cooling subsystems of a server rack), different variants of a given product (e.g., a base vehicle model, a mid-range vehicle model, a top end vehicle model, etc.), and the like.

As 3D objects modeled through CAD data continue to increase in complexity, effective visualization of such 3D CAD models may also become increasingly complex. To visualize the internal CAD parts of a given 3D product or product component, computer systems may support exploded views of 3D CAD models in which the 3D CAD parts that form a given CAD model are visually separated (e.g., “exploded”) from one another to reveal the internal components and structure of the 3D model. Exploded views (also referred to as exploded model representations) of CAD models may likewise illustrate a global structure of CAD models in a separated form, in which the details of individual CAD parts are maintained to illustrate the structure of components that form a given 3D object.

Various techniques exist to support generation of exploded views of CAD models, for example as described in Li et al., “Automated Generation of Interactive 3D Exploded View Diagrams”, ACM Transactions on Graphics, Vol. 27, Issue 3 Aug. 2008 (referred to herein as “Li”) as well as Agrawala et al., “Designing Effective Step-by-Step Assembly Instructions”, ACM Transactions on Graphics, Vol. 22, Issue 3, July 2003 (referred to herein as “Agrawala”). Both Li and Agrawala are incorporated by reference herein in their entirety. While conventional techniques such as those described in Li and Agrawal may provide baseline exploded CAD view capabilities, improvements to the efficiency, clarity, and visual coherency of exploded CAD model views can improve computational performance and user experience.

The disclosure herein may provide systems, methods, devices, and logic for generation of exploded views of CAD models. As described in greater detail herein, various model explosion features are disclosed that may increase the efficiency, effectiveness, clarity, spatial visualization, and visual coherency of CAD model explosions. For instance, the model explosion features described herein may support consideration of blocking relationships among a greater degree of the CAD parts that form a CAD model, including between CAD parts that are not directly adjacent, in contact, or touching one another. Such an increased consideration of blocking relationships for a CAD model may decrease visual obstructions and improve clarity in exploded CAD model views. As another example, the model explosion features described herein may control separation movement in exploded view generations with increased effectiveness through selection of primary parent CAD parts via parent determination criteria. The parent determinations described herein may improve the visual and logical stacking of parts in an exploded view representation, which may improve the visual and spatial coherency of exploded CAD model views.

These and other model explosion features and technical benefits are described in greater detail herein.

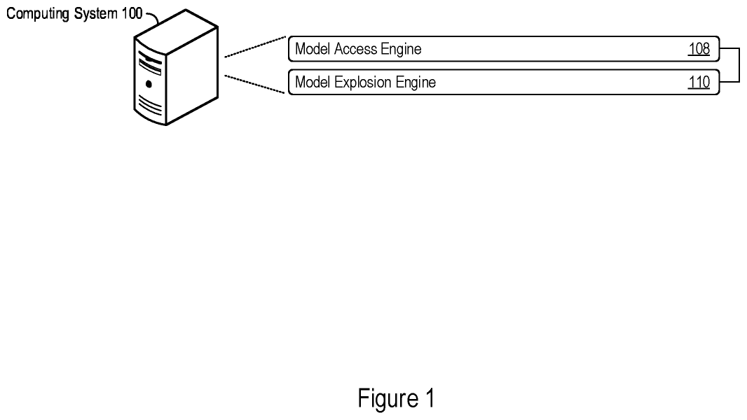

FIG. 1 shows an example of a computing system 100 that supports generation of exploded views of CAD models according to the present disclosure. The computing system 100 may take the form of a single or multiple computing devices such as application servers, compute nodes, desktop or laptop computers, smart phones or other mobile devices, tablet devices, embedded controllers, and more. In some implementations, the computing system 100 hosts, supports, executes, or implements a CAD application that supports the generation of exploded views for CAD models.

As an example implementation to support any combination of the model explosion features described herein, the computing system 100 shown in FIG. 1 includes a model access engine 108 and a model explosion engine 110. The computing system 100 may implement the engines 108 and 110 (including components thereof) in various ways, for example as hardware and programming. The programming for the engines 108 and 110 may take the form of processor-executable instructions stored on a non-transitory machine-readable storage medium and the hardware for the engines 108 and 110 may include a processor to execute those instructions. A processor may take the form of single processor or multi-processor systems, and in some examples, the computing system 100 implements multiple engines using the same computing system features or hardware components (e.g., a common processor or a common storage medium).

In operation, the model access engine 108 may access a CAD model comprised of multiple CAD parts. As noted herein, a CAD model may represent a product or components thereof, and may include any number of CAD parts that together form the CAD model.

In operation, the model explosion engine 110 may construct a blocking data structure for the CAD model that stores a blocking state for each pair of CAD parts among the multiple CAD parts of the CAD model. The blocking state for a particular pair of CAD parts that include a first CAD part and a second CAD part of the multiple CAD parts may specify explosion directions, if any, in a set of predetermined explosion directions that the first CAD part collides with the second CAD part when moving along the explosion directions and an escape distance for each given explosion direction in the set of predetermined explosion directions that the first CAD part does not collide with the second CAD part when moving along the given explosion direction. An escape distance may specify a distance along the given explosion direction at which no portion of the first CAD part is within a bounding box of the second CAD part.

In operation, the model explosion engine 110 may also construct an explosion graph for the CAD model, for example doing so by iteratively adding nodes into the explosion graph, and each node may represent a different CAD part of the CAD model. To construct the explosion graph, the model explosion engine 110 may, for a given iteration, query the blocking data structure to determine a set of candidate CAD parts to add to the explosion graph from a set of active CAD parts for the CAD model (wherein each candidate CAD part in the set of candidate CAD parts is not blocked by any other CAD part in the set of active CAD parts in at least one explosion direction), select a particular CAD part from the set of candidate CAD parts with a lowest escape distance, add a node in the explosion graph to represent the particular CAD part, add an edge from the node to each CAD part in the set of active CAD parts that collides with the particular CAD part in at least one of the explosion directions, and remove the particular CAD part selected for the given iteration from the set of active CAD parts. Multiple such iterations may be performed by the model explosion engine 110 until the explosion graph is constructed. Then, the model explosion engine 110 may generate an exploded view representation of the CAD model using the constructed explosion graph.

These and other model explosion features are described in greater detail next.

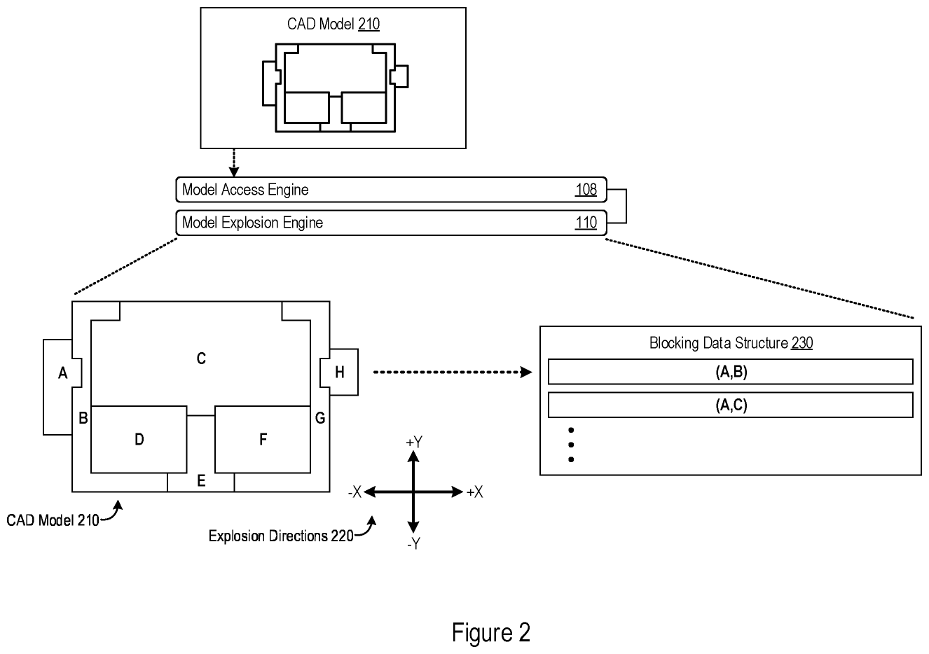

FIG. 2 shows an example construction of a blocking data structure according to the present disclosure in support of exploded CAD model views. The example shown in FIG. 2 is presented through a computing system implemented through a model access engine 108 and a model explosion engine 110, though other implementations are contemplated herein.

In the example shown in FIG. 2, the model access engine 108 accesses a CAD model 210. As used herein, a CAD model may include any data that digitally represents an object, and need not be limited specifically to computer-aided design applications. As such, CAD models may include any product, part, or object data for any computer-aided technology, including object data for CAE, PLM, PDM, or other systems. The model access engine 108 may access CAD models in any number of ways, e.g., by loading stored model data from application databases or local system memories.

The CAD model 210 may represent a particular 3-dimensional (or other multi-dimensional) object or product. In that regard, the CAD model 210 may be comprised of multiple different CAD parts, each of which may be a discrete component of the CAD model 210 that is to be separately visualized in an exploded view representation of the CAD model 210. The CAD parts that comprise the CAD model 210 may thus be individual CAD components, or in the form of CAD assemblies comprised of multiple CAD components grouped together as a single entity to separately visualize in an exploded view of the CAD model 210.

The model access engine 108 may support abstraction of any number of components of a CAD model to form the CAD parts to be exploded and separated via an exploded view representation. For instance, specific sets of sub-components, CAD assemblies, or other object items may be grouped together the model access engine 108 into a given CAD part. Such CAD parts may then be considered for explosion and separation in generation of an exploded view of the CAD model 210, with the grouped components represented as a single CAD part. In some examples, CAD models may be represented as a hierarchical tree, and the model access engine 108 may support the abstraction (e.g., grouping) of specified nodes, leafs, or portions of the hierarchical tree into discrete CAD parts, e.g., via user input.

To support exploded view generations for the CAD model 210, the model explosion engine 110 may process the CAD parts that form the CAD model 210 according to a predetermined set of explosion directions. In doing so, the model explosion engine 110 may construct a blocking data structure to track blocking states between the various CAD parts of the CAD model 210. The blocking states may specify the extent to which different CAD parts of the CAD model 210 collide with one another along any number of the set of explosion directions. To determine blocking states among CAD parts of the CAD model 210, the model explosion engine 110 may apply any of the capabilities described in Li and Agrawala, and further improve on them as well.

An example construction of a blocking data structure for the CAD model 210 is illustrated in FIG. 2. For visual simplicity, the CAD model 210 shown in FIG. 2 is illustrated as a 2D model, but the features described herein may be consistently applied for 3D CAD models or any other multi-dimensional models. In FIG. 2, the CAD model 210 is depicted to include seven (7) different CAD parts as an illustrative example, with each of the CAD parts labeled respectively with letters A-H.

The model explosion engine 110 may determine blocking states among the different CAD parts A-H for a predetermined set of explosion directions. In some implementations, the model explosion engine 110 uses the coordinate axes of a global coordinate system in which a CAD model is represented as the predetermined set of explosion directions. For a 2D coordinate system used to represent the CAD model 210, the model explosion engine 110 may determine blocking states for CAD parts A-H based on the predetermined set of explosion directions 220 shown in FIG. 2, which include four (4) distinct explosion directions labeled and referred to as +X, −X, +Y, and −Y explosion directions. For a 3D CAD model, the model explosion engine 110 may also apply an additional two (2) explosion directions along each direction of a Z-axis (e.g., further include +Z and −Z explosion directions in the predetermined set of explosion directions 220), as the X, Y, and Z axes may be part of a global coordinate system used to represent the 3D CAD model.

In some implementations, the model explosion engine 110 may apply custom explosion directions for determination of blocking states for selected CAD parts of a CAD model. For instance, the model explosion engine 110 may apply additional or alternative explosion directions for any given CAD part that is represented in a local coordinate system different than the global coordinate system used to represent the CAD model of which the given CAD part is a part of.

To illustrate through FIG. 2, CAD part C of the CAD model 210 may be represented in a local coordinate system in which the X and Y axes of the local coordinate system are rotated by 45° clockwise (referred to as rotated X and Y axes in this local coordinate system for CAD part C). For blocking states that include CAD part C, the model explosion engine 110 may determine blocking states along, for example, eight (8) different explosion directions, including the explosion directions 220 of the global coordinate system used to represent the CAD model 210 (that is, +X, −X, +Y, and −Y) as well as explosion directions for the local coordinate system of CAD part C (that is, explosion directions for the rotated +X axis, rotated −X, rotated +Y axis, and rotated −Y axis). In a consistent manner, custom explosion directions may be determined and applied by the model explosion engine 110 for 3D CAD models and 3D CAD parts as well.

To determine a blocking state for a pair of CAD parts of the CAD model 210, the model explosion may process the two different CAD parts of the CAD model 210 along each explosion direction applied for the blocking state computation. In doing so, the model explosion engine 110 may determine which of the explosion directions (if any) that the two CAD parts block one another as well as any of the explosion directions in which the two CAD parts do not block one another. In some implementations, the model explosion engine 110 may determine a blocking state for a pair of CAD parts in the CAD model 210, including a first CAD part and a second CAD part, to include (i) explosion directions, if any, in the explosion directions 220 that the first CAD part collides with the second CAD part when moving along the explosion directions 220 and (ii) an escape distance for each given explosion direction in the explosion directions 220 that the first CAD part does not collide with the second CAD part when moving along the given explosion direction. The escape distance may, for example, specify a distance along a given explosion direction at which no portion of the first CAD part is within a bounding box of the second CAD part or is otherwise sufficiently distant from the second CAD part.

To provide an example blocking state determination through FIG. 2, the model explosion engine 110 may compute a blocking state between CAD part A and CAD part B of the CAD model 210. For this pair of CAD parts, the model explosion engine 110 may determine which, if any, of the explosion directions in which CAD part A and CAD part B block one another. In one example, the model explosion engine 110 may determine which of the explosion directions 220 in which CAD part A collides with CAD part B when moving along each of the explosion directions 220. In this example, the model explosion engine 110 may determine that CAD part B blocks CAD part A along three (3) of the explosion directions 220, namely the +X, +Y, and −Y explosion directions. As CAD parts A and B are in contact with one another in CAD model 210 (e.g., touching or with directly adjacent part boundaries or perimeters), it can be seen that CAD part B directly blocks CAD part A in the +X, +Y, and −Y explosion directions for any movement distance on these explosion directions. In such a manner, the model explosion engine 110 may determine which explosion directions among the explosion directions 220 that a pair of CAD parts block one another as part of a blocking state computation for the pair of CAD parts.

In computing a blocking state between a pair of CAD parts, the model explosion engine 110 may determine a blocking distance for each explosion direction in which the CAD parts block one another. For blocked explosion directions in which the two CAD parts are directly in contact or adjacent to one another, the model explosion engine 110 may determine a blocking distance of zero (0). For CAD parts that are spatially separated (either by open space or other intervening CAD parts), the model explosion engine 110 may compute the distance at which the CAD parts collide for each blocked explosion direction. Such blocking distances determined for blocking state computations may be tracked or otherwise stored in blocking state entries of a blocking data structure.

As part of the blocking state computation, the model explosion engine 110 may also determine which (if any) of the explosion directions 220 in which the pair of CAD parts do not block another (also referred to herein as “unblocked”). Continuing the illustrative example with CAD parts A and B of the CAD model 210, when CAD part A moves along the −X explosion direction, CAD part A will not collide with CAD part B. Accordingly, the model explosion engine 110 may determine an escape distance for the −X explosion direction for CAD parts A and B, which may take the form of a distance along the −X explosion direction at which no portion of the CAD part A is within the bounding box of CAD part B (or vice versa, or both). Escape distances may be determined by the model explosion engine 110 in any number of ways, e.g., as a function of the distance to extend past a bounding box of a different part, as a predetermined or a fixed distance from the different part, or as any other separation distance value determined or otherwise configured for CAD parts.

Note that the explosion directions at which a pair of CAD parts collide may be inverse to another for each of the individual CAD parts. For CAD part A, the model explosion engine 110 may determine that CAD part B blocks CAD part A in the +X direction. For CAD part B on the other hand, the model explosion engine 110 may instead determine that CAD part A blocks CAD part B in the −X direction (inverse to the +X direction determined for CAD part A with respect to CAD part B). For a blocking state computed for the CAD part A-CAD part B pair, the model explosion engine 110 may track explosion directions at which the CAD parts block one another in different ways, whether by specifying the blocked explosion directions for a selected one of the CAD parts (and thus implicitly storing the inverse blocked explosion directions for the non-selected CAD part) or by expressly storing blocked explosion directions for both of the CAD parts in the blocking state computation. Different implementation variations are contemplated herein.

In any such ways as described herein, the model explosion engine 110 may obtain, compute, or otherwise determine blocking states between pairs of CAD parts of a CAD model. The blocking state may, in a general sense, indicate to what degree the pair of CAD parts block one another along the explosion directions applied for the blocking state computation. As such, the exact form in which model explosion engine 110 tracks blocking states may vary based on implementation preferences. In some examples, the model explosion engine 110 may represent computed blocking states on a pair-wise basis (e.g., a computed blocking state for the CAD part A and CAD part B pair), e.g., as an array values comprising flags for the explosion directions in which the CAD parts collide or block one another as well as escape distances for non-blocked explosion directions, etc. Other implementations are contemplated as well, so long as the represented blocking states specify, for example, blocked explosion directions for the CAD part pair and escape distances for unblocked explosion directions.

The model explosion engine 110 may store computed blocking states among CAD parts of a CAD model in a blocking data structure. In the example of FIG. 2, the model explosion engine 110 constructs the blocking data structure 230 in which the model explosion engine 110 stores blocking states computed for CAD parts of the CAD model 210. The model explosion engine 110 may construct a blocking data structure (such as the blocking data structure 230) in any form in which blocking states computed for CAD parts of a CAD model can be stored. For instance, the model explosion engine 110 may construct the blocking data structure 230 by initializing, generating, or populating a data structure (e.g., table, linked list, relational database) to store computed blocking states for the CAD model 210. The blocking data structure 230 may be locally or remotely implemented.

In some implementations, the model explosion engine 110 may compute blocking states for each CAD part pair of a CAD model. Using the CAD model 210 of FIG. 2 as an illustrative example, the model explosion engine 110 may compute blocking states for each pair of CAD part combinations among CAD parts A-H (which may result in 21 different unordered pairs of CAD parts). In comparison to other conventional techniques that only compute blocking states between CAD parts directly in contact with one another, the blocking state computations described herein may increase the blocking state coverage of the CAD model 210, allowing consideration of blocking relationships and exploded view generations that account for the impact between CAD parts that are not directly in contact, separated by an open space, or otherwise spatially-distant within a CAD model. The model explosion engine 110 may thus construct the blocking data structure 230 for the CAD model 210 by computing a blocking state for pairs of CAD parts that are not in contact with one another in the CAD model 210 (e.g., including the blocking state for CAD parts A and C shown as an example in FIG. 2).

To further illustrate through the blocking data structure 230 of FIG. 2, the model explosion engine 110 may compute and store a blocking state for CAD parts A and B (touching/directly in contact in the CAD model 210) as well as another blocking state for CAD parts A and C (not touching, not directly in contact in the CAD model 210). By computing a blocking state for CAD parts A and C (even when separated in between by CAD part B in the CAD model 210), the model explosion engine 110 may account for blocking states of different CAD parts which may be separated by open space or otherwise separated by another CAD part which may be separated (e.g., exploded) earlier in generation of an exploded view for a CAD model.

For example, in generation of an exploded view of a 3-dimensional version of CAD model 210, CAD part B may be exploded in a +Z direction before CAD parts A and C are exploded, and the blocking data structure 230 storing an blocking state entry for CAD parts A and C can thus indicate blocking states in the X direction in which CAD parts A and C block one another even after CAD part B is separated from an unexploded portion of the 3D CAD model. Such an entry and explosion consideration would not be possible for blocking state computations limited only to CAD parts that directly contact one another. Accordingly, the model explosion engine 110 may provide increased blocking state considerations for a CAD model by computing blocking states for CAD parts that do not directly contact one another in a CAD model, which may increase the capability and visual coherency of exploded CAD model views by allowing for increased blocking state considerations and blocking relationship evaluations among the different CAD parts that form a CAD model.

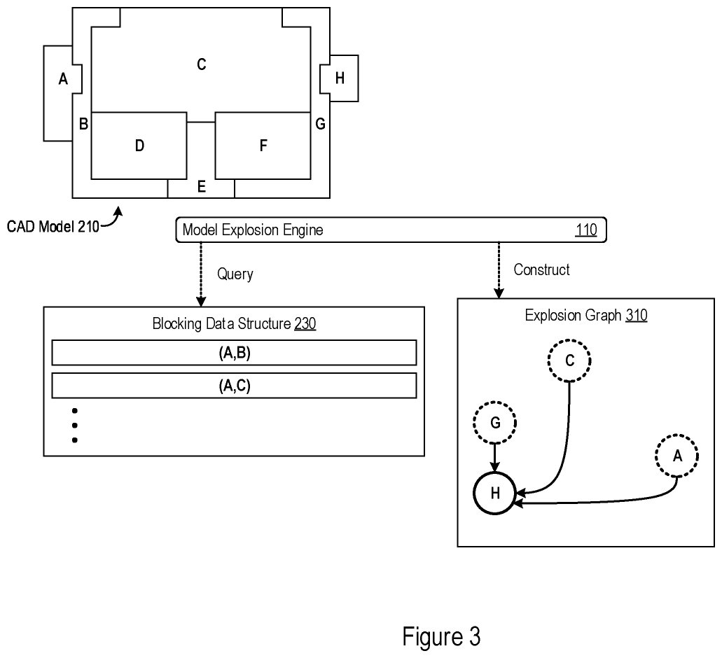

As described with reference to FIG. 2, the model explosion engine 110 may construct a blocking data structure for a CAD model to track different blocking states among the various CAD parts of the CAD model. In some implementations, the model explosion engine 110 may configure the blocking data structure to support blocking state queries, in which a query to the blocking data structure 230 with specified CAD parts as input parameters may return an indication of the blocking state for the specified CAD parts relative to one another. Such an output from a query to the blocking data structure 230 may, for example, return a lowest escape distance (and corresponding explosion direction) for each given CAD part with respect to the other specified CAD parts or an indication that a given CAD part is completely blocked by the other specified CAD parts. Such a query and output may be used in the construction of an explosion graph to support generation of exploded CAD model views. Example features with regards to explosion graph constructions are described next with reference to FIG. 3.

FIG. 3 shows an example construction of an explosion graph by the model explosion engine 110 according to the present disclosure. In constructing an explosion graph, the model explosion engine 110 may apply any of the features described in Li and Agrawala, but may further do so with any number of additional or alternative features as described herein to improve the efficiency, blocking relationship coverage, and visual coherency of exploded CAD model views. The explosion graph may represent (implicitly or expressly) a separation sequence to be used in generating an exploded view representation of a CAD model. In some implementations constructed explosion graphs may be in the form of directed acyclic graphs, with directed edges that may indicate blocking relationships between the different CAD parts of the CAD model as explained in greater detail herein. To construct an explosion graph, the model explosion engine 110 may iteratively add nodes into the explosion graph, each node representing a different CAD part of a CAD model.

Next, an example explosion graph construction process will be described using the CAD model 210 as an example, and the model explosion engine 110 may construct an explosion graph 310 for the CAD model 210 using the constructed blocking data structure 230 (e.g., as described herein with reference to FIG. 2). Prior to or during an initial iteration of the explosion graph construction process, the model explosion engine 110 may initialize a set of active CAD parts to include all of the multiple CAD parts that form the CAD model 210. In this example, the model explosion engine 110 may initialize the set of active CAD parts to include each of CAD parts A-H of the CAD model 210. The set of active CAD parts may represent the set of CAD parts from which to determine an explosion sequence, with CAD parts earlier in an explosion sequence added into the explosion graph in earlier iterations of the explosion graph construction process. Iteration by iteration, CAD parts added as nodes into the explosion graph (and thus into an explosion sequence) may be removed from the set of active CAD parts until no active CAD parts remain and the process completes.

In a given iteration of the explosion graph construction process, the model explosion engine 110 may query the blocking data structure 230 to determine a set of candidate CAD parts to add to the explosion graph 310 from the set of active CAD parts for the CAD model 210. The model explosion engine 110 may determine the set of candidate CAD parts as any CAD part among the set of active CAD parts that is not blocked in at least one explosion direction by the other CAD parts of the set of active CAD parts. As such, each candidate CAD part in the set of candidate CAD parts may be unblocked with respect to each other CAD part in the set of active CAD parts in at least one explosion direction. In each iteration, the set of active CAD parts may be updated as nodes are added to the explosion graph 310 such that a subsequent iteration may have a lesser number of active CAD parts to consider. Iterations may continue until each CAD part of a CAD model 210 has been added to the explosion graph 310.

In an iteration for constructing the explosion graph 310 for the CAD model 210, the model explosion engine 110 may query the blocking data structure 230 to determine the set of candidate CAD parts. The model explosion engine 110 may do so by passing, as input parameters, the set of active CAD parts for a given iteration. In the example of an initial iteration of the explosion graph construction process for CAD model 210, the CAD parts A-H of the CAD model 210 may together form the set of active CAD parts, which the model explosion engine 110 may pass as an input to the blocking data structure 230. The blocking data structure 230 may respond to the query with an identification of CAD parts among the set of active CAD parts that are unblocked in at least in one explosion direction by the other CAD parts of the set of active CAD parts.

In this initial iteration for the CAD model 210, the blocking data structure 230 may respond to the query by specifying that CAD part A and CAD part H are not blocked in at least one explosion direction by any other CAD part among the set of active CAD parts. This may be the case for the initial iteration as CAD part A is not blocked in the −X explosion direction by any other CAD parts in the set of active CAD parts (i.e., CAD parts B-H in this example) and CAD part H is not blocked in the +X explosion direction by any other CAD parts in the set of active CAD parts (i.e., CAD parts A-G in this example). As can be seen in FIG. 2, CAD parts B-G are blocked by at least one other CAD part in the set of active CAD parts in each of the explosion directions 220. As such, for an initial iteration, the model explosion engine 110 may determine that CAD part A and CAD part H form the set of candidate CAD parts from which to insert a node into the explosion graph 310.

After determining the set of candidate CAD parts to add to the explosion graph 310, the model explosion engine 110 may select a particular CAD part from the set of candidate CAD parts to add to the explosion graph 310. In some implementations, the model explosion engine 110 may select the candidate CAD part with a lowest escape distance. In doing so, the model explosion engine 110 may determine a lowest escape distance (e.g., minimum value) that each candidate CAD part would have to move to escape the bounding box of the other active CAD parts in given iteration (including those that do not directly contact or touch a given candidate CAD part). As noted herein, escape distance values may be specified, measured, or determined in any number of ways to sufficiently separate a given CAD part from other CAD parts.

The model explosion engine 110 may evaluate escape distances among the set of candidate CAD parts specifically along the explosion direction(s) that each of the candidate CAD parts are unblocked in (e.g., the escape distance for CAD part A along the −X direction and the escape distance for CAD part H along the +X direction). In some instances, a candidate CAD part may be unblocked by other CAD parts in the set of active CAD parts in multiple explosion directions, and the model explosion engine 110 may consider each of these different unblocked explosion directions in selection of one of the candidate CAD parts for insertion into the explosion graph 310.

In some instances, multiple candidate CAD parts in the set of candidate CAD parts have an escape distance that is the lowest escape distance value among the set of candidate CAD parts. This may be the case in the example initial iteration in constructing the explosion graph 310 for the CAD model 210 since CAD part A and CAD part H may have identical escape distances (e.g., equal in value). To elaborate further, the distance for CAD part A to escape the bounding box of CAD part B along the −X explosion direction may be the same (e.g., equal to) the distance for CAD part H to escape the bounding box of CAD part G along the +X explosion direction. In such cases, to select a particular CAD part from the set of candidate CAD parts, the model explosion engine 110 may identify multiple CAD parts in the set of candidate CAD parts each with an escape distance that is the lowest escape distance and (in response) determine the particular CAD part to insert into the explosion graph 310 as a given CAD part with a lowest part volume among the multiple CAD parts in the set of candidate CAD parts each with an escape distance that is the lowest escape distance.

In the initial iteration of the continuing example described herein for constructing the explosion graph 310, the model explosion engine 110 may select CAD part H from the set of candidate CAD parts, doing so responsive to a determination that CAD part H has a lower volume than CAD part A (or area for a 2D model). By selecting CAD parts with lower volume (among candidate CAD parts, each having the lowest escape distance), the model explosion engine 110 may improve visual sequencing in generation of exploded views by ensuring smaller parts are exploded/separated earlier in the exploded view generation. By exploding smaller CAD parts earlier in an explosion sequence, the visual coherency of the exploded view representation may be improved, e.g., by ensuring that smaller parts are exploded further out than larger CAD parts (in volume) such that these larger parts do not obscure other smaller parts that may otherwise be separated later in the exploded view generation.

As such, for a given iteration, the model explosion engine 110 may select a particular CAD part among the set of candidate CAD parts as described herein. Upon selecting a particular CAD part among the candidate CAD parts in the given iteration, the model explosion engine 110 may remove the particular CAD part from the set of active CAD parts and may add a node in the explosion graph 310 to represent the particular CAD part selected for the given iteration. The model explosion engine 110 may also add an edge directed into the node for each CAD part in the set of active CAD parts that collides, in at least one explosion direction, with the particular CAD part selected in the given iteration. The edge(s) directed into the node and added in a given iteration may indicate which of the active CAD parts that the particular CAD part blocks in at least one explosion direction. As such, when the particular CAD part represented by the node is separated in an explosions sequence of an exploded view representation, the connected nodes linked via directed edges to the particular CAD part may become unblocked (at least in part).

In the example of FIG. 3, the model explosion engine 110 selects CAD part H in an initial iteration of the explosion graph construction process and may thus add a node for CAD part H in the explosion graph 310. Then, the model explosion engine 110 may determine which CAD parts among the set of active CAD parts that CAD part H collides with (e.g., blocks) in at least one explosion direction. In this example, the determined CAD parts include CAD part G (blocked in the −X, +Y, and −Y directions for CAD part H), CAD part C (blocked in the −X direction for CAD part H), and CAD part A (blocked in the −X direction for CAD part H). Accordingly, the model explosion may add three (3) directed edges in the explosion graph 310 into the node inserted for CAD part H. Even though nodes for CAD parts G, C, and A have not yet been inserted into the explosion graph 310, the model explosion engine 110 may nonetheless add the directed edges into the node for CAD part H, and further link or otherwise indicate the other end of the inserted edges will connect to nodes for CAD parts G, C, and A when such nodes are eventually inserted in subsequent iterations of the explosion graph construction process.

Note that model explosion engine 110 may insert directed edges that link to nodes of other CAD parts that are not in direct contact with the CAD part for which a node was inserted in a given iteration. This is seen in the example of FIG. 3, as the model explosion engine 110 inserts directed edges in the explosion graph 310 directed into the node for CAD part H and coming from nodes for CAD part C and CAD part A, doing so even though CAD part H is not in contact with, directly adjacent to, or touching CAD part C or CAD part A in the CAD model 210. By inserting an increased number of directed edges (as compared to other techniques limited only to CAD parts in direct contact), explosion graphs constructed according to the present disclosure may store an increased amount of blocking relationships among the different CAD parts of a CAD model, providing a fuller understanding, consideration, coverage, and accounting of blocking and spatial relationships among CAD parts of the CAD model.

Explosion graphs constructed according to the present disclosure may thus provide a fuller representation of blocking relationships, allowing generation of exploded views with increased data and improved visual coherency. In particular, blocking relationships of CAD parts separated by open space (whether as part of the CAD model design or based on explosions of other CAD parts earlier in the explosion sequence) may nonetheless be represented in the explosion graphs of the present disclosure, which may yield increasingly intelligent and effective explosions that would otherwise be impossible in explosion graphs and blocking relationship determinations limited only to CAD parts that are directly adjacent or in contact with one another.

In a given iteration during construction of an explosion graph, the model explosion engine 110 may determine that no single CAD part among the set of active CAD parts is unblocked in at least one explosion direction by the other CAD parts of the set of active CAD parts. Such a scenario may arise, for example, when the set of active CAD parts includes interlocking CAD parts that completely block one another and also block or enclose the other active CAD parts in the set of active CAD parts. In such a situation, the model explosion engine 110 may determine that no single CAD part is eligible for inclusion in the set of candidate CAD parts for which to insert a node into the explosion graph.

In response to such a determination, the model explosion engine 110 may consider a combination of multiple active CAD parts for which to insert a node into the explosion graph. For instance, the model explosion engine 110 may query the blocking data structure for a CAD model to determine a combination of two CAD parts in the set of active CAD parts that is not blocked by any other CAD part in the set of active CAD parts in at least one explosion direction. Then, the model explosion engine 110 may add a single node in the explosion graph to represent the combination of the two CAD parts, add directed edges into the node for any other CAD parts that are blocked in at least one explosion direction by the combination of the two CAD parts, and remove the two CAD parts that form the combination from the set of active CAD parts.

In considering CAD part combinations, the model explosion engine 110 may generate multiple different queries as combinations of different CAD parts to potentially group together. Using an illustrative example in which a set of active CAD parts includes CAD part₁, CAD part₂, CAD part₃, CAD part₄, and CAD part₅ in a given iteration, the model explosion engine 110 may determine that none of CAD part₁, CAD part₂, CAD part₃, CAD part₄, or CAD part₅ is unblocked in at least one explosion direction by the other CAD parts in the set of active CAD parts. In response, the model explosion engine 110 may generate different queries to the blocking data structure for various combinations of CAD parts among the set of active CAD parts. Using a potential combination of CAD part₁ and CAD part₂ as an illustrative example, the model explosion engine 110 may query the blocking data structure to determine whether the CAD part₁-CAD part₂ combination is unblocked by CAD part₃, CAD part₄, and CAD part₅.

In some implementations the model explosion engine 110 may do so by sending two separate queries to the blocking data structure. The model explosion engine 110 may send a first query to ascertain whether CAD part₁ is unblocked in any explosion direction(s) by CAD part₃, CAD part₄, and CAD part₅ as well as a second query as to whether CAD part₂ is unblocked in any explosion direction(s) by CAD part₃, CAD part₄, and CAD part₅. If both the first query and second query return a same explosion direction (or multiple same explosion directions), then the model explosion engine 110 may determine that the CAD part₁-CAD part₂ combination is unblocked by CAD part₃, CAD part₄, and CAD part₅ in such explosion directions and thus include the CAD part₁-CAD part₂ combination in the set of candidate CAD parts for which to add node in the construction graph. In a similar manner, the model explosion engine 110 may generate queries for other CAD part combinations in the set of active parts, even doing so for triple CAD part combinations, quadruple CAD part combinations, etc.

In such a manner, the model explosion engine 110 may combine multiple different CAD parts into a single node for insertion into an explosion graph. In effect, the model explosion engine 110 may treat the combination of different CAD parts as a single logical entity, and the combination of CAD parts may be combined as the single logical entity in exploded view generations. In supporting such combination features, the model explosion engine 110 may address gridlock situations that may occur in generation of exploded views, and thus allow for exploded view generation in which other conventional techniques may stall, produce an error, or otherwise fail.

In some implementations, the model explosion engine 110 may construct the explosion graph in a nested manner, such that one or more nodes of the explosion graph represent a different explosion graph. In such a way, the model explosion engine 110 may support representation of CAD sub-assemblies as given nodes in an explosion graph for a CAD model, and such CAD sub-assemblies may further be represented via explosion graphs of the CAD components (e.g., CAD parts) that form the CAD subassemblies. Along similar lines, nodes of CAD part combinations (e.g., the CAD part₁-CAD part₂ combination described above) may be nested nodes, in that the model explosion engine 110 may support subsequent explosion/separation of the CAD part₁ and CAD part₂ from one another after the CAD part₁-CAD part₂ combination is separated from an unexploded portion of a CAD model. As such, the model explosion engine 110 may support eventual separation and explosion of individual CAD parts even when multiple CAD parts are separated together to address gridlock situations, which may improve the effectiveness, spatial position, as well as visual accuracy of exploded CAD model views.

As described herein, the model explosion engine 110 may iteratively add nodes into an explosion graph, and continue to add nodes and edges into the explosion graph until no CAD parts remain in the set of active CAD parts. The constructed explosion graph may then include a node for each CAD part in a CAD model and directed edges representing blocking relationships based on an insertion sequence of nodes into the explosion graph. Understood in a different way, a constructed explosion graph may represent an explosion sequence by which an exploded view representation of a CAD model can be generated. The explosion sequence may be specified by acyclic directed edges in the explosion graph in that a node without any outgoing edges can be separated/exploded from a CAD model in generation of an exploded view. As nodes (and incoming edges) are removed sequentially in an explosion sequence, additional nodes (and thus CAD parts) are eligible for explosion, until eventually each CAD part of the CAD model is separated from one another in an exploded view representation of the CAD model.

In support of separating CAD parts to form an exploded view representation, the model explosion engine 110 may embed or otherwise store explosion data in the explosion graph 310. Embedded explosion data may direct the generation of an exploded view representation in various ways, and examples of embedded data may include explosion directions, escape distances, and primary parent data. The explosion distance and escape distance for a given CAD part may be stored as explosion data linked to the node of the given CAD part in the explosion graph. The explosion direction and escape distance may together specify which direction and a separation distance that a given CAD part will be exploded/separated from an exploded portion of a CAD model in generation of an exploded view representation for the CAD model.

Returning to the example in FIG. 3, the model explosion engine 110 may construct the explosion graph 310 by inserting an explosion direction and escape distance into each node of the explosion graph 310. In some implementations, the model explosion engine 110 need not additionally calculate such values, and instead utilize the explosion direction and escape distance determined during selection of a given CAD part during the given iteration the node for the given CAD part was inserted into the explosion graph 310. For CAD part H (selected in an initial iteration of the explosion graph construction process), the model explosion engine 110 may use the lowest escape distance that caused the model explosion engine 110 to select CAD part H for insertion into the explosion graph 310 as well as the corresponding explosion direction of the lowest escape distance, correlating such explosion data to the node of the explosion graph 310 inserted for CAD part H (e.g., in this case, the −X explosion direction and the distance to escape the bounding box of CAD part G).

When generating the exploded view representation of the CAD model 210, the explosion data for CAD part H embedded in the explosion graph 310 may be used to specify the direction and distance to separate CAD part H from a remaining unexploded portion of the CAD model 210. For a specific CAD part that is separated from the CAD model during an explosion sequence in generating the exploded view representation, the model explosion engine 110 may separate the given CAD part along the explosion direction and by (at least or as a function of) the escape distance specified in the explosion data for the given CAD part. However, for other parts already separated (e.g., earlier in the explosion sequence), the model explosion engine 110 may limit, restrict, or correlate movement to such parts based on the movement of a primary parent specified for such CAD parts.

A primary parent of a given CAD part may refer to a different CAD part in a CAD model for which separation movement of the given CAD part is tied to after the given CAD part has been separated/exploded in the explosion sequence. Thus, it follows that a given CAD part will be separated earlier in the explosion sequence than its primary parent, and the movement of the given CAD part in subsequent separations in the explosion sequence will be controlled by the movement of the primary parent instead of based on the explosion direction and escape distance of the given CAD part (though in some cases, such movement will be along the explosion direction). Explained in yet another way, the separation of a given CAD part itself from a CAD model in an explosion sequence may be controlled by the CAD part's own explosion direction and escape distance. For separation of other CAD parts later in explosion sequence, the movement of the given CAD part may be tied directly, controlled, or otherwise based on the movement of its primary parent.

To illustrate through FIG. 3, CAD part H may have a primary parent set in the explosion graph 310 as CAD part G. When CAD part H is separated from the CAD model 210 in generation of an exploded view, the model explosion engine 110 may separate CAD part H from the CAD model 210 along the explosion direction and as a function of the escape distance set for CAD part H (e.g., along the +X direction by a function of the distance to escape the bounding box of CAD part G). For the next CAD part separated from the CAD model 210 after CAD part H, the separation movement of CAD part H may be controlled by the movement of CAD part G (CAD part H's primary parent) instead of the explosion direction and escape distance of CAD part H. As an example, CAD part A may be exploded and separated from the CAD model 210 next in a determined explosion sequence, in which case CAD part H may not move at all, since CAD part G has not moved and is still part of the unexploded portion of the CAD model 210 in the exploded view generation process.

At some point in the explosion sequence, the model explosion engine 110 may separate CAD part G from the unexploded portion of the CAD model 210. As an illustrative example, CAD part G may have a +X explosion direction with an escape distance set to escape the bounding box of CAD part F. In such case, the model explosion engine 110 may separate CAD part G from the unexploded portion of the CAD model 210 along the +X direction and by a function of the escape distance of CAD part G. In doing so, the model explosion engine 110 may also further separate CAD part H to an identical degree, to maintain the previously implemented separation of CAD part H from CAD part G. As such, it may be understood that a CAD part moves rigidly or consistently with respect to its primary parent after separation of the CAD part from a CAD model. Doing so may keep a consistent spatial separation of a given CAD part from its primary parent during subsequent CAD part separations in generation of exploded CAD model views.

The determination of a primary parent for CAD parts of a CAD model may affect correlated movements in the various CAD parts of the CAD model in generation of exploded view, thus impacting the visual effectiveness of exploded CAD model views. Ineffective selection of primary parents for CAD parts may result in obstructed views and visual dissonance in exploded CAD model views, which can lower the effectiveness, visibility, or clarity at which different CAD parts are depicted in an exploded CAD model view. Various primary parent determination features are provided herein that can improve the visual coherency, effectiveness, and clarity of generated exploded views.

In some implementations, the model explosion engine 110 may identify a unique primary parent for each respective CAD part of a CAD model via various parent determination criteria. The parent determination criteria disclosed herein may allow for primary parent selections that increase the visual coherency of exploded views, and may do so by prioritizing specific positional or blocking characteristics between CAD parts to increase visibility and clarity of exploded CAD model views. The model explosion engine 110 may apply any combination of parent determination criteria to determine a primary parent for the CAD parts that form a CAD model, some examples of which are described next.

In some examples, the model explosion engine 110 determines a unique primary parent for CAD parts of a CAD model concurrent with or as part of the construction of an explosion graph for the CAD model. (Note, in other implementations, the model explosion engine 110 may set primary parents for CAD parts after construction of the explosion graph has completed, doing so by applying any of primary parent determination features and criteria described herein.) As part of constructing an explosion graph for a CAD model, the model explosion engine 110 may set a primary parent for a given node in the explosion graph, including by identifying a set of candidate parent nodes of the explosion graph, wherein each candidate parent node is connected to or to be connected to the given node by an edge directed into the given node.

As the model explosion engine 110 may iteratively insert nodes into an explosion graph, determination and setting of a primary parent for a given node may occur prior to insertion of the parent node in the explosion graph. This may necessarily be the case as the model explosion engine 110 may insert children nodes prior to parent nodes, and thus identification and setting of a primary parent for a given child node can occur in an iteration of the explosion graph construction process at which the parent node is not yet inserted into the explosion graph.

To illustrate through the example shown in FIG. 3, the model explosion engine 110 may determine a primary parent for CAD part H, and may do so during the iteration in the explosion graph construction process in which the node for CAD part H is inserted into the explosion graph 310. As noted above, the model explosion engine 110 may insert a node for CAD part H as well as directed edges into the node inserted for CAD part H (namely from nodes for CAD parts G, C, and A among the set of active CAD parts that collide with CAD part H, even though such nodes have not yet been inserted into the explosion graph 310). The model explosion engine 110 may identify the set of nodes with directed edges into a given node (e.g., for CAD part H in this example) as the set of candidate parent nodes for the given node.

Such a set of candidate parent nodes (e.g., nodes for CAD parts G, C, and A) may yet to be inserted into the explosion graph 310, and will be inserted by the model explosion engine 110 into the explosion graph 310 in subsequent iterations of the explosion graph construction process. As such, each candidate parent node for CAD parts G, C, and A may be understood as “to be connected” to a given node, particularly as the model explosion engine 110 may insert the directed edges into the node for CAD part H in the iteration the node for CAD part H is inserted into the explosion graph 310. As referred to herein, the CAD parts represented by the set of candidate parent nodes for a given node may be referred to as parent CAD parts and the CAD part represented by the given node may be referred to as a child CAD part.

From the set of candidate parent nodes identified for a given node, the model explosion engine 110 may select the primary parent node for the given node based on any number of parent determination criteria. In some implementations, the model explosion engine 110 applies an ordered set of parent determination criteria that may comprise multiple different criterion that the model explosion engine 110 may successively apply until a unique primary parent is selected from the set of candidate parent nodes. In some sense, each of the multiple different parent determination criterion may filter the set of candidate parent nodes, and the model explosion engine 110 may continue to filter the set of candidate parent nodes for a given node until only a single (and thus unique) candidate parent node remains, which the model explosion engine 110 may set as the primary parent node for a given node.

As an illustrative example, the model explosion engine 110 may apply the following parent determination criteria in succession: (i) the candidate parent node for a parent CAD part that is closest to the child CAD part represented by the given node (e.g., the parent CAD part with the least distance from the child CAD part), (ii) the candidate parent node for a parent CAD part that collides with the child CAD part represented by the given node in a highest number of explosion directions, (iii) the candidate parent node for a parent CAD part that extends furthest in an explosion direction of the child CAD part represented by the given node subject to an extension limitation criterion, and (iv) the candidate parent node for a parent CAD part with a highest volume. Additional or alternative parent determination criteria are contemplated, which may be applied in various orders by the model explosion engine 110.

To further elaborate, if multiple candidate parent nodes satisfy parent determination criterion (i) for a closet parent CAD part (e.g., multiple parent CAD parts that are in direct contact with or touch a child CAD part), the model explosion engine 110 may the apply parent determination criterion (ii) for the multiple candidate parent nodes that satisfy parent determination criterion (i). If the model explosion engine 110 then determines more than one candidate parent node satisfies both parent determination criteria (i) and (ii), then the model explosion engine 110 may further apply parent determination criterion (iii). In a consistent manner, the model explosion engine 110 may continue to apply successive parent determination criteria until a single candidate parent is determined and selected as the primary parent for a child CAD part.

Some aspects and benefits of various parent determination criteria to select a primary parent for a given node of a particular child CAD part are explained in greater detail next.

As noted herein, the model explosion engine 110 may apply a parent determination criterion that selects, as the primary parent, the candidate parent node for the closest CAD part to a CAD part represented by the given node. In applying such a parent determination criterion, the model explosion engine 110 may account for positional and spatial relationships between the different CAD parts of a CAD model. In setting a primary parent for a particular child CAD part, correlating movements of the child CAD part to a spatially-closer parent CAD part may improve visual effectiveness of an exploded view, e.g., in comparison to setting a parent CAD part that is separated by a further distance in a CAD model. Further distances may result in part obstructions, particularly as exploded views with CAD parts exploding in different explosion directions may result in overlap or partially blocked views in the exploded view visualization. In some cases, a child CAD part may have multiple parent candidates that directly touch or contact the child CAD part. As such, it may be helpful for the model explosion engine 110 to further filter the multiple candidate parents that satisfy a closest or least distance criterion.

The model explosion engine 110 may further apply a parent determination criterion that selects, as the primary parent, a parent CAD part that blocks the child CAD part to a greatest degree, e.g., as measured in blocked explosion directions. By applying such a criterion, the model explosion engine 110 may filter a set of candidate parent nodes to determine a parent CAD part that limits movement of a child CAD part in the highest number of explosion directions. In doing so, the model explosion engine 110 may correlate the movement of the child CAD part to another CAD part that most limits movement of the child CAD part. Such circumstances may occur when a parent CAD part wraps, envelops, or otherwise encloses (at least in part) a given child CAD part in multiple dimensions and along multiple explosion directions. Thus, by setting such a parent CAD part as the primary parent for a child CAD part, the model explosion engine 110 may preserve a spatial coherency and logical interlocking between the two CAD parts. Doing so may improve the visual clarity of an exploded CAD view due to the degree of perimeter overlap between such CAD parts, as opposed to correlating explosion movement to a different parent CAD part that only blocks the CAD part in a single or lesser number of explosion directions (and may only be bordering or adjacent to the child CAD part in an ancillary manner).

As noted herein, the model explosion engine 110 may apply parent determination criteria in combination, doing so in the case in which more than one candidate parent nodes satisfy a first parent determination criterion (e.g., multiple parent CAD parts touch a child CAD part and thus each satisfy a least distance parent determination criterion). That is, the model explosion engine 110 may determine there are multiple parent CAD parts represented in the set of candidate parent nodes that are closest in distance to a child CAD part represented by a given node. To select the primary parent for the given node, the model explosion engine 110 may then apply a second parent determination criterion (and so in combination with the first parent determination criterion), e.g., by selecting a given candidate parent node that (i) represents a particular parent CAD part that is closest in distance, in the CAD model, to the child CAD part represented by the given node and (ii) collides with the child CAD part represented by the given node in a highest number of explosion directions.

The model explosion engine 110 may apply yet another parent determination criterion, such as a criterion that is satisfied by the candidate parent node for a parent CAD part that extends furthest in an explosion direction of the child CAD part represented by the given node, subject to an extension limitation criterion. The extension limitation may exclude any parent CAD parents that extend beyond the child CAD part itself in the explosion direction. To illustrate, the model explosion engine 110 may determine that multiple parent CAD parts to a child CAD part each touch the child CAD part (and thus satisfy parent determination criterion (i) described above) and each block the child CAD part in a highest number of explosion directions among the candidate parents (and thus also satisfy parent determination criterion (ii) described above). The model explosion engine 110 may further filter the multiple parent CAD parts based on a spatial criterion based on the extent to which each of the multiple parent CAD parts extend along the explosion direction of the child CAD part.

By applying such a parent determination criterion, the model explosion engine 110 may account for spatial extent of child and parent CAD parts, by prioritizing selection of CAD parents with geometry, shapes, or portions that align and extend along the explosion direction of a child CAD part. Doing so may improve the visual clarity of an exploded view, since separating two CAD parts with shapes that extend in the same explosion direction along such an explosion direction may improve visual consistency in exploded views. Explained in another way, application of such a parent determination criterion may promote a logical stacking of CAD parts together in an exploded view, which may improve visual clarity and coherency.

The model explosion engine 110 may limit such extensions for visual clarity via an extension limitation criterion. When a candidate parent CAD part extends too far in the explosion direction of the child CAD part, visual awkwardness and discontinuity may occur, and the model explosion engine 110 may reduce such effects by excluding any parent CAD parts with a part portion that extends beyond the child CAD part in the explosion direction of the CAD part (or by any other extension limitation along an explosion direction). As an illustrative example in which a child CAD part has a +X explosion direction and the shape of the child CAD part extends furthest along the X-dimension to a value of 10.0 (e.g., in a global coordinate system of the CAD model), the model explosion engine 110 may identify a candidate parent node of the parent CAD part that extends furthest in the +X direction of the X-dimension and that does not extend past +10.0 in the X-dimension. For a set of candidate CAD parents with part elements that extend in the X-dimension to values of −5.0, +9.0, and +13.0 respectively, the model explosion engine 110 may select the parent CAD part that extends to +9.0 in the X-dimension and set the node of this parent CAD part as the primary parent for the child CAD part. The extension limitation criterion may filter out the parent CAD part that extends +13.0 along the X-dimension, since this parent CAD part extends past the furthest extent along the X-dimension of child CAD part.

As yet another example of a parent determination criterion, the model explosion engine 110 may select a parent CAD part with a highest volume (for 3D CAD models). Doing so may improve visual clarity by linking movement of child CAD parts to a CAD parts with greater volume.

While some examples of parent determination criteria are described herein, additional and alternative parent determination criteria are contemplated herein. Any combination of parent determination criteria may be applied, and in varying orders to select a primary parent for nodes of an explosion graph. The model explosion engine 110 may track selected primary parents as explosion data embedded in the explosion graph, e.g., by inserting an indication of the primary parent for each node as a data value appended to or correlated to the node in the explosion graph.

In any of the ways described herein, the model explosion engine 110 may construct an explosion graph for a CAD model, which may also include determining and embedding explosion data (such as explosion directions, escape distances, and primary parent identifiers) for the nodes of the explosion graph. The model explosion engine 110 may then generate an exploded view representation of a CAD model through the explosion graph generated for the CAD model.

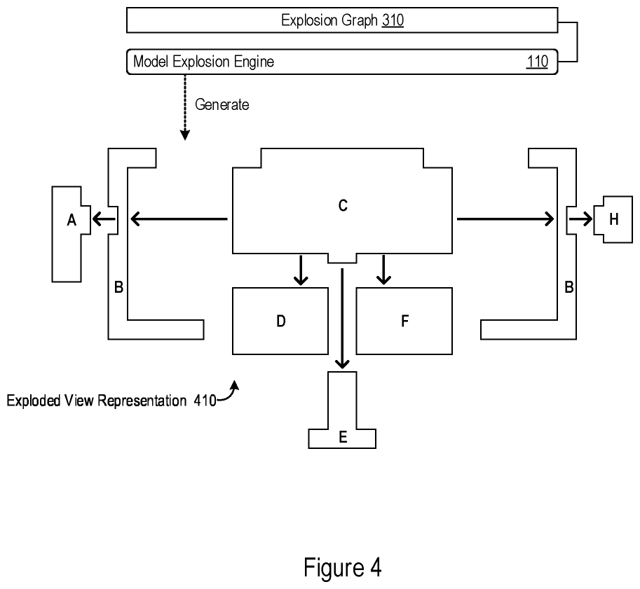

FIG. 4 shows an example generation of an exploded view representation by the model explosion engine 110. In the example of FIG. 4, the model explosion engine 110 uses the explosion graph 310 constructed for a CAD model 210 to generate the exploded view representation 410 of the CAD model 210. As noted herein, the explosion graph 310 may (expressly or implicitly) specify a separation order for CAD parts of a CAD model, based on the acyclic graph representation.

CAD parts representing nodes without any outgoing directed edges may be separated as part of generation of the exploded view representation, and in an explosion direction and distance specified as explosion data of the explosion graph 310. As CAD parts are separated in the exploded view representation, the model explosion engine 110 may mark the nodes in the explosion graph 310 and edges directed into the nodes as removed, and then continue to separate CAD parts for nodes without outgoing edges until no nodes are marked as unremoved in the explosion graph.

As described herein, separation movement of CAD parts may be controlled by an explosion direction and separation distance for the CAD parts when the CAD parts are separated from an unexploded portion of the CAD model, and then subsequently by the primary parent of the CAD parts during separation of other CAD parts from the exploded portion of the CAD model. As the model explosion engine may construct the explosion graph 310 according to the various features described herein, the exploded view representation 410 generated via the explosion graph 310 may result in improved visual coherence and clarity, increased logical stacking of parts, reduced visual dissonance and part obstruction, or any combination of additional or alternative technical benefits as described herein.

In some instances, a CAD model may include mistakes or errors, such as when CAD parts overlap in volume or otherwise interfere with one another. Such overlap may be a mistake since two CAD parts cannot occupy the same point in a 3D object. Conventional techniques may be unable to deal with such mistakes, which may result in erroneous blocking state computations and propagate into incorrect explosion graph construction and erroneous explode view generations. The model explosion engine 110 may address such CAD model mistakes by computing forced explosions.

To explain further, the model explosion engine 110 may compute a blocking state between two CAD parts that overlap or interfere with one another, e.g., within a threshold overlap value between the two CAD parts (e.g., less than a fixed volume of overlap, less than fixed percentage of a volume the two CAD parts, etc.). In particular, the model explosion engine 110 may logically infer a blocking state for the two CAD parts moving the CAD parts along the explosion direction(s) and determining the impact on the overlap volume.

For a given explosion direction (e.g., +X), the model explosion engine 110 may move a first CAD part of the two CAD parts along the explosion direction. Responsive to a determination that the overlap volume between the two CAD parts increases, then the model explosion engine 110 may determine that the second CAD part blocks the first CAD part in the explosion direction. Responsive to a determination that the overlap volume between the two CAD parts decreases or does not change, then the model explosion engine 110 may determine that the first CAD part is unblocked by the second CAD part in the explosion direction, and escape distances can be computed accordingly. As such, the model explosion engine 110 may be capable of determining blocking states even amongst overlapping CAD parts, and support generation of blocking data structures and including such CAD parts in explosion graphs to support exploded view generations for such CAD models.

While many based model explosion features have been described herein through illustrative examples presented through various figures, the model access engine 108 or the model explosion engine 110 may implement any combination of the model explosion features described herein.

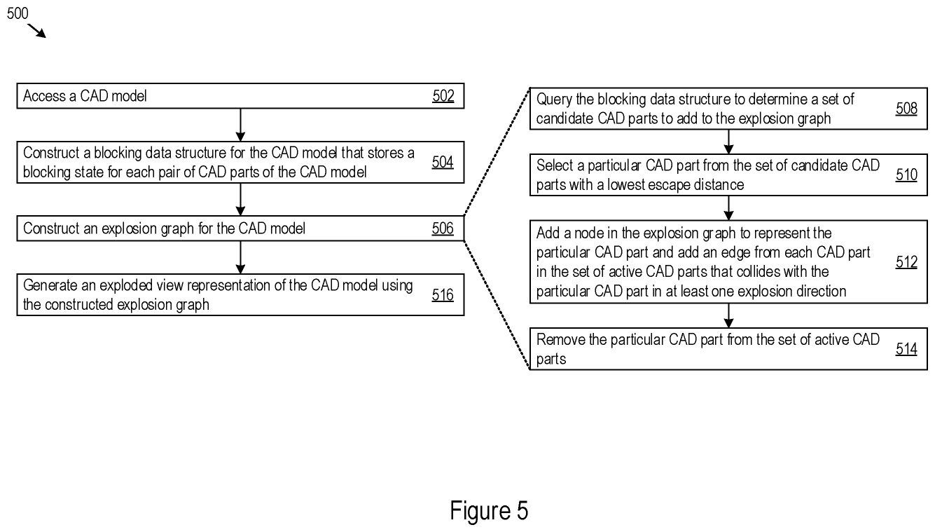

FIG. 5 shows an example of logic 500 that a system may implement to support generation of exploded views of CAD models according to the present disclosure. For example, the computing system 100 may implement the logic 500 as hardware, executable instructions stored on a machine-readable medium, or as a combination of both. The computing system 100 may implement the logic 500 via the model access engine 108 and the model explosion engine 110, through which the computing system 100 may perform or execute the logic 500 as a method to support generation of exploded views of CAD models according to the present disclosure. The following description of the logic 500 is provided using the model access engine 108 and the model explosion engine 110 as examples. However, various other implementation options by computing systems are possible.

In implementing the logic 500, the model access engine 108 may access a CAD model (502). In implementing the logic 500, the model explosion engine 110 may construct a blocking data structure for the CAD model that stores a blocking state for each pair of CAD parts of the CAD model (504), doing so in any of the ways described herein. The model explosion engine 110 may also construct an explosion graph for the CAD model (506), for example in an iterative manner as described herein. In doing so, the model explosion engine 110 may initialize a set of active CAD parts to include all of the multiple CAD parts that form the CAD model, doing so prior to or during a first iteration of constructing the explosion graph.

For a given iteration in construction of the explosion graph, the model explosion engine 110 may query the blocking data structure to determine a set of candidate CAD parts to add to the explosion graph (508) and select a particular CAD part from the set of candidate CAD parts with a lowest escape distance (510). In the given iteration, the model explosion engine 110 may also add a node in the explosion graph to represent the particular CAD part and add an edge from each CAD part in the set of active CAD parts that collides with the particular CAD part in at least one explosion direction (512) as well as remove the particular CAD part from the set of active CAD parts (514). In such a manner, the model explosion engine 110 may iteratively construct the explosion graph, doing so until no CAD parts of the CAD model remain in the set of active CAD parts.

In implementing the logic 500, the model explosion engine 110 may also generate an exploded view representation of the CAD model using the constructed explosion graph (516).

The logic 500 shown in FIG. 5 provides an illustrative example by which a computing system 100 may support generation of exploded views of CAD models according to the present disclosure. Additional or alternative steps in the logic 500 are contemplated herein, including according to any of the various features described herein for the model access engine 108, the model explosion engine 110, or any combinations thereof.

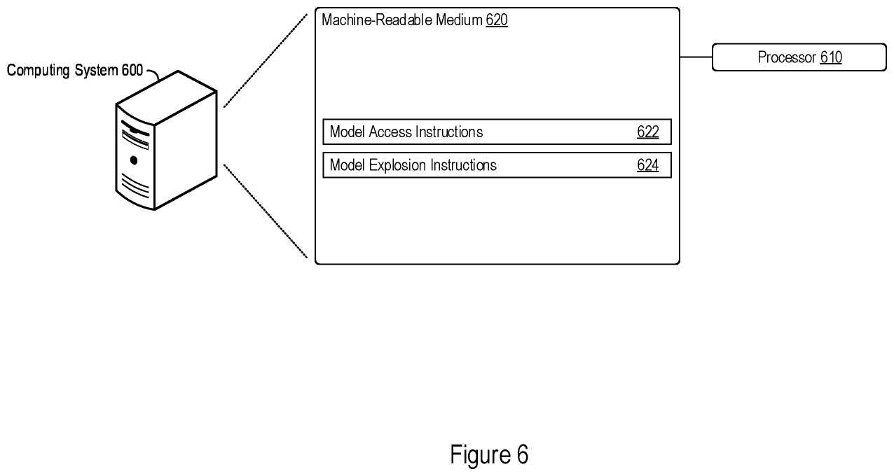

FIG. 6 shows an example of a computing system 600 that supports generation of exploded views of CAD models according to the present disclosure. The computing system 600 may include a processor 610, which may take the form of a single or multiple processors. The processor(s) 610 may include a central processing unit (CPU), microprocessor, or any hardware device suitable for executing instructions stored on a machine-readable medium. The computing system 600 may include a machine-readable medium 620. The machine-readable medium 620 may take the form of any non-transitory electronic, magnetic, optical, or other physical storage device that stores executable instructions, such as the model access instructions 622 and the model explosion instructions 624 shown in FIG. 6. As such, the machine-readable medium 620 may be, for example, Random Access Memory (RAM) such as a dynamic RAM (DRAM), flash memory, spin-transfer torque memory, an Electrically-Erasable Programmable Read-Only Memory (EEPROM), a storage drive, an optical disk, and the like.

The computing system 600 may execute instructions stored on the machine-readable medium 620 through the processor 610. Executing the instructions (e.g., the model access instructions 622 and/or the model explosion instructions 624) may cause the computing system 600 to perform any of the model explosion features described herein, including according to any of the features of the model access engine 108, the model explosion engine 110, or combinations of both.

For example, execution of the model access instructions 622 by the processor 610 may cause the computing system 600 to access a CAD model comprised of multiple CAD parts. As noted herein, a CAD model may represent a product or components thereof, and may include any number of CAD parts that together form the CAD model.

Execution of the model explosion instructions 624 by the processor 610 may cause the computing system 600 to construct a blocking data structure for the CAD model that stores a blocking state for each pair of CAD parts among the multiple CAD parts of the CAD model. The blocking state for a particular pair of CAD parts that include a first CAD part and a second CAD part of the multiple CAD parts may specify explosion directions, if any, in a set of predetermined explosion directions that the first CAD part collides with the second CAD part when moving along the explosion directions and an escape distance for each given explosion direction in the set of predetermined explosion directions that the first CAD part does not collide with the second CAD part when moving along the given explosion direction. An escape distance may specify a distance along the given explosion direction at which no portion of the first CAD part is within a bounding box of the second CAD part.

Execution of the model explosion instructions 624 by the processor 610 may also cause the computing system 600 to construct an explosion graph for the CAD model, for example doing so by iteratively adding nodes into the explosion graph, and each node may represent a different CAD part of the CAD model. For a given iteration in construction of the explosion graph, execution of the model explosion instructions 624 may cause the computing system 600 to query the blocking data structure to determine a set of candidate CAD parts to add to the explosion graph from a set of active CAD parts for the CAD model (wherein each candidate CAD part in the set of candidate CAD parts is not blocked by any other CAD part in the set of active CAD parts in at least one explosion direction), select a particular CAD part from the set of candidate CAD parts with a lowest escape distance, add a node in the explosion graph to represent the particular CAD part, add an edge from the node to each CAD part in the set of active CAD parts that collides with the particular CAD part in at least one of the explosion directions, and remove the particular CAD part selected for the given iteration from the set of active CAD parts. Multiple such iterations may be performed by the model explosion engine 110 until the explosion graph is constructed. Execution of the model explosion instructions 624 may then cause the computing system 600 to generate an exploded view representation of the CAD model using the constructed explosion graph.

Any additional or alternative model explosion features as described herein may be implemented via the model access instructions 622, model explosion instructions 624, or a combination of both.

The systems, methods, devices, and logic described above, including the model access engine 108 and the model explosion engine 110, may be implemented in many different ways in many different combinations of hardware, logic, circuitry, and executable instructions stored on a machine-readable medium. For example, the model access engine 108, the model explosion engine 110, or combinations thereof, may include circuitry in a controller, a microprocessor, or an application specific integrated circuit (ASIC), or may be implemented with discrete logic or components, or a combination of other types of analog or digital circuitry, combined on a single integrated circuit or distributed among multiple integrated circuits. A product, such as a computer program product, may include a storage medium and machine-readable instructions stored on the medium, which when executed in an endpoint, computer system, or other device, cause the device to perform operations according to any of the description above, including according to any features of the model access engine 108, the model explosion engine 110, or combinations thereof.

The processing capability of the systems, devices, and engines described herein, including the model access engine 108 and the model explosion engine 110, may be distributed among multiple system components, such as among multiple processors and memories, optionally including multiple distributed processing systems or cloud/network elements. Parameters, databases, and other data structures may be separately stored and managed, may be incorporated into a single memory or database, may be logically and physically organized in many different ways, and may be implemented in many ways, including data structures such as linked lists, hash tables, or implicit storage mechanisms. Programs may be parts (e.g., subroutines) of a single program, separate programs, distributed across several memories and processors, or implemented in many different ways, such as in a library (e.g., a shared library).

While various examples have been described above, many more implementations are possible.

1. A method comprising:
by a computing system:
accessing a computer-aided design (CAD) model comprised of multiple CAD parts;
constructing a blocking data structure for the CAD model that stores a blocking state for each pair of CAD parts among the multiple CAD parts of the CAD model, wherein the blocking state for a particular pair of CAD parts, including a first CAD part and a second CAD part of the multiple CAD parts, specifies:
explosion directions, if any, in a set of predetermined explosion directions that the first CAD part collides with the second CAD part when moving along the explosion directions; and
an escape distance for each given explosion direction in the set of predetermined explosion directions that the first CAD part does not collide with the second CAD part when moving along the given explosion direction, wherein the escape distance specifies a distance along the given explosion direction at which no portion of the first CAD part is within a bounding box of the second CAD part; and
constructing an explosion graph for the CAD model by iteratively adding nodes into the explosion graph, each node representing a different CAD part of the CAD model, wherein constructing the explosion graph comprises, for a given iteration:
querying the blocking data structure to determine a set of candidate CAD parts to add to the explosion graph from a set of active CAD parts for the CAD model, wherein each candidate CAD part in the set of candidate CAD parts is not blocked by any other CAD part in the set of active CAD parts in at least one explosion direction;
selecting a particular CAD part from the set of candidate CAD parts with a lowest escape distance;
adding a node in the explosion graph (310) to represent the particular CAD part and adding an edge from the node to each CAD part in the set of active CAD parts that collides with the particular CAD part in at least one of the explosion directions; and
removing the particular CAD part selected for the given iteration from the set of active CAD parts; and
generating an exploded view representation of the CAD model using the constructed explosion graph.

2. The method of claim 1, wherein constructing the blocking data structure (230) for the CAD model comprises computing a blocking state for a pair of CAD parts that are not in contact with one another in the CAD model.

3. The method of claim 1, wherein constructing the explosion graph comprises initializing the set of active CAD parts to include all of the multiple CAD parts that form the CAD model prior to or during a first iteration of constructing the explosion graph.

4. The method of claim 1, wherein selecting the particular CAD part from the set of candidate CAD parts comprises:
identifying multiple CAD parts in the set of candidate CAD parts each with an escape distance that is the lowest escape distance; and
determining the particular CAD part as a given CAD part with a lowest part volume among the multiple CAD parts in the set of candidate CAD parts each with an escape distance that is the lowest escape distance.

5. The method of claim 1, wherein constructing the explosion graph further comprises setting a primary parent for a given node in the explosion graph, including by:
identifying a set of candidate parent nodes of the explosion graph, wherein each candidate parent node is connected to or to be connected to the given node by an edge directed into the given node; and
selecting, as the primary parent for the given node, a given candidate parent node that represents a particular CAD part closest in distance, in the CAD model, to the CAD part represented by the given node.

6. The method of claim 5, wherein setting the primary parent for the given node further comprises determining there are multiple CAD parts represented in the set of candidate parent nodes that are closest in distance to the CAD part represented by the given node; and
wherein selecting the primary parent for the given node comprises selecting a given candidate parent node that represents a particular CAD part that:
is closest in distance, in the CAD model, to the CAD part represented by the given node; and
collides with the CAD part represented by the given node in a highest number of explosion directions.

7. The method of claim 1, wherein constructing the explosion graph further comprises determining that none of CAD parts in the set of active CAD parts are unblocked in at least one explosion direction, and in response:
querying the blocking data structure to determine a combination of two CAD parts in the set of active CAD parts is not blocked by any other CAD part in the set of active CAD parts in at least one explosion direction;
adding a node in the explosion graph to represent the combination of the two CAD parts; and
removing the two CAD parts that form the combination from the set of active CAD parts.

8. A system comprising:
a model access engine configured to access a computer-aided design (CAD) model comprised of multiple CAD parts; and
a model explosion engine configured to:
construct a blocking data structure for the CAD model that stores a blocking state for each pair of CAD parts among the multiple CAD parts of the CAD model, wherein the blocking state for a particular pair of CAD parts, including a first CAD part and a second CAD part of the multiple CAD parts, specifies:
explosion directions, if any, in a set of predetermined explosion directions that the first CAD part collides with the second CAD part when moving along the explosion directions; and
an escape distance for each given explosion direction in the set of predetermined explosion directions that the first CAD part does not collide with the second CAD part when moving along the given explosion direction, wherein the escape distance specifies a distance along the given explosion direction at which no portion of the first CAD part is within a bounding box of the second CAD part; and
construct an explosion graph for the CAD model by iteratively adding nodes into the explosion graph, each node representing a different CAD part of the CAD model, including by, for a given iteration:
querying the blocking data structure to determine a set of candidate CAD parts to add to the explosion graph from a set of active CAD parts for the CAD model, wherein each candidate CAD part in the set of candidate CAD parts is not blocked by any other CAD part in the set of active CAD parts in at least one explosion direction;
selecting a particular CAD part from the set of candidate CAD parts with a lowest escape distance;
adding a node in the explosion graph to represent the particular CAD part and adding an edge from the node to each CAD part in the set of active CAD parts that collides with the particular CAD part in at least one of the explosion directions; and
removing the particular CAD part selected for the given iteration from the set of active CAD parts; and
generate an exploded view representation of the CAD model using the constructed explosion graph.

9. The system of claim 8, wherein the model explosion engine is configured to construct the blocking data structure for the CAD model by computing a blocking state for a pair of CAD parts that are not in contact with one another in the CAD model.

10. The system of claim 8, wherein the model explosion engine is configured to construct the explosion graph by initializing the set of active CAD parts to include all of the multiple CAD parts that form the CAD model prior to or during a first iteration of constructing the explosion graph.

11. The system of claim 8, wherein the model explosion engine is configured to select the particular CAD part from the set of candidate CAD parts by:
identifying multiple CAD parts in the set of candidate CAD parts each with an escape distance that is the lowest escape distance; and
determining the particular CAD part as a given CAD part with a lowest part volume among the multiple CAD parts in the set of candidate CAD parts each with an escape distance that is the lowest escape distance.

12. The system of claim 8, wherein the model explosion engine is configured to construct the explosion graph further by setting a primary parent for a given node in the explosion graph, including by:
identifying a set of candidate parent nodes of the explosion graph, wherein each candidate parent node is connected to or to be connected to the given node by an edge directed into the given node; and
selecting, as the primary parent for the given node, a given candidate parent node that represents a particular CAD part closest in distance, in the CAD model, to the CAD part represented by the given node.

13. The system of claim 12, wherein the model explosion engine is configured to set the primary parent for the given node further by determining there are multiple CAD parts represented in the set of candidate parent nodes that are closest in distance to the CAD part represented by the given node; and
wherein the model explosion engine is configured to select the primary parent for the given node by selecting a given candidate parent node that represents a particular CAD part that:
is closest in distance, in the CAD model, to the CAD part represented by the given node; and
collides with the CAD part represented by the given node in a highest number of explosion directions.

14. The system of claim 8, wherein the model explosion engine is configured to construct the explosion graph further by determining that none of CAD parts in the set of active CAD parts are unblocked in at least one explosion direction, and in response:
querying the blocking data structure to determine a combination of two CAD parts in the set of active CAD parts is not blocked by any other CAD part in the set of active CAD parts in at least one explosion direction;
adding a node in the explosion graph to represent the combination of the two CAD parts; and
removing the two CAD parts that form the combination from the set of active CAD parts.

15. A non-transitory machine-readable medium comprising instructions that, when executed by a processor, cause a computing system to:
access a computer-aided design (CAD) model comprised of multiple CAD parts;
construct a blocking data structure for the CAD model that stores a blocking state for each pair of CAD parts among the multiple CAD parts of the CAD model, wherein the blocking state for a particular pair of CAD parts, including a first CAD part and a second CAD part of the multiple CAD parts, specifies:
explosion directions, if any, in a set of predetermined explosion directions that the first CAD part collides with the second CAD part when moving along the explosion directions; and
an escape distance for each given explosion direction in the set of predetermined explosion directions that the first CAD part does not collide with the second CAD part when moving along the given explosion direction, wherein the escape distance specifies a distance along the given explosion direction at which no portion of the first CAD part is within a bounding box of the second CAD part; and
construct an explosion graph for the CAD model by iteratively adding nodes into the explosion graph, each node representing a different CAD part of the CAD model, including by, for a given iteration:
querying the blocking data structure to determine a set of candidate CAD parts to add to the explosion graph from a set of active CAD parts for the CAD model, wherein each candidate CAD part in the set of candidate CAD parts is not blocked by any other CAD part in the set of active CAD parts in at least one explosion direction;
selecting a particular CAD part from the set of candidate CAD parts with a lowest escape distance;
adding a node in the explosion graph to represent the particular CAD part and adding an edge from the node to each CAD part in the set of active CAD parts that collides with the particular CAD part in at least one of the explosion directions; and
removing the particular CAD part selected for the given iteration from the set of active CAD parts; and
generate an exploded view representation of the CAD model using the constructed explosion graph.

16. The non-transitory machine-readable medium of claim 15, wherein the instructions, when executed, cause the computing system to construct the blocking data structure for the CAD model by computing a blocking state for a pair of CAD parts that are not in contact with one another in the CAD model.

17. The non-transitory machine-readable medium of claim 15, wherein the instructions, when executed, cause the computing system to select the particular CAD part from the set of candidate CAD parts by:
identifying multiple CAD parts in the set of candidate CAD parts each with an escape distance that is the lowest escape distance; and
determining the particular CAD part as a given CAD part with a lowest part volume among the multiple CAD parts in the set of candidate CAD parts each with an escape distance that is the lowest escape distance.

18. The non-transitory machine-readable medium of claim 15, wherein the instructions, when executed, cause the computing system to construct the explosion graph further by setting a primary parent for a given node in the explosion graph, including by:
identifying a set of candidate parent nodes of the explosion graph, wherein each candidate parent node is connected to or to be connected to the given node by an edge directed into the given node; and
selecting, as the primary parent for the given node, a given candidate parent node that represents a particular CAD part closest in distance, in the CAD model, to the CAD part represented by the given node.

19. The system of claim 18, wherein the instructions, when executed, cause the computing system to set the primary parent for the given node further by determining there are multiple CAD parts represented in the set of candidate parent nodes that are closest in distance to the CAD part represented by the given node; and
wherein the instructions, when executed, cause the computing system to select the primary parent for the given node by selecting a given candidate parent node that represents a particular CAD part that:
is closest in distance, in the CAD model, to the CAD part represented by the given node; and
collides with the CAD part represented by the given node in a highest number of explosion directions.

20. The non-transitory machine-readable medium of claim 15, wherein the instructions, when executed, cause the computing system to construct the explosion graph further by determining that none of CAD parts in the set of active CAD parts are unblocked in at least one explosion direction, and in response:
querying the blocking data structure to determine a combination of two CAD parts in the set of active CAD parts is not blocked by any other CAD part in the set of active CAD parts in at least one explosion direction;
adding a node in the explosion graph to represent the combination of the two CAD parts; and
removing the two CAD parts that form the combination from the set of active CAD parts.
